(19) United States
(12) Patent Application Publication
(10) Pub. No.: US 2023/0378311 A1
(43) Pub. Date: Nov. 23, 2023

(54) PN JUNCTION

(71) Applicants: STMicroelectronics (Rousset) SAS, Rousset (FR); STMicroelectronics (Crolles 2) SAS, Crolles (FR)

(72) Inventors: Guillaume GUIRLEO, Marseille (FR); Abderrezak MARZAKI, Aix en Provence (FR); Thomas CABOUT, Grenoble (FR)

(73) Assignees: STMicroelectronics (Rousset) SAS, Rousset (FR); STMicroelectronics (Crolles 2) SAS, Crolles (FR)

(21) Appl. No.: 18/197,420

(22) Filed: May 15, 2023

(30) Foreign Application Priority Data
May 18, 2022 (FR) 2204712

(51) Int. Cl. H01L 29/66; H01L 21/02; H01L 21/308; H01L 21/762

(52) U.S. Cl. CPC H01L 29/66136; H01L 21/02381; H01L 21/308; H01L 21/0262; H01L 21/02293; H01L 21/76224

(57) ABSTRACT

A method of manufacturing a PN junction includes successive steps for: forming at least one trench in a semiconductor substrate of a first conductivity type; and filling the at least one trench with a semiconductor material of a second conductivity type, different from the first conductivity type.

### PRIORITY CLAIM

This application claims the priority benefit of French Application for Patent No. 2204712, filed on May 18, 2022, the content of which is hereby incorporated by reference in its entirety to the maximum extent allowable by law.

### TECHNICAL FIELD

The present disclosure generally concerns electronic systems and devices and, in particular, their manufacturing methods. The present disclosure more particularly concerns a PN junction manufacturing method.

### BACKGROUND

The manufacturing and the use of ever higher performance electronic systems and devices is a significant issue in today's industry. Further, the miniaturization of electronic systems and devices while keeping their operating performance may be a problem.

It would be desirable to be able to improve, at least partly, known electronic systems and devices, and in particular, their manufacturing methods.

There is a need in the art for higher-performance electronic systems and devices comprising a PN junction.

There is a need in the art for electronic systems and devices comprising an abrupt PN junction.

There is a need in the art for higher-performance electronic device manufacturing methods.

There is a need in the art for higher-performance PN junction manufacturing methods.

There is a need in the art for PN junction manufacturing methods enabling to obtain a more abrupt PN junction.

There is a need in the art for higher-performance diode manufacturing methods.

There is a need in the art for higher-performance bipolar transistor manufacturing methods.

There is a need in the art to overcome all or part of the disadvantages of known electronic device manufacturing methods.

There is a need in the art to overcome all or part of the disadvantages of known diodes.

There is a need in the art to overcome all or part of the disadvantages of known bipolar transistors.

### SUMMARY

An embodiment provides a PN junction manufacturing method comprising the following successive steps: forming at least one trench in a semiconductor substrate of a first conductivity type; and filling said at least one trench with a semiconductor material of a second conductivity type, different from the first conductivity type.

According to an embodiment, at least two trenches are formed in said substrate.

According to an embodiment, the step of deposition of said material is a furnace deposition step.

According to an embodiment, the step of deposition of said material is an epitaxial deposition step.

Another embodiment provides a diode manufacturing method using the previously-described PN junction manufacturing method.

Another embodiment provides a diode comprising a doped semiconductor substrate of a first conductivity type and at least one first region made of a semiconductor material of a second conductivity type, different from the first conductivity type, wherein said first region has a uniform doping.

According to an embodiment, the diode further comprises at least one second region made of a semiconductor material of a second conductivity type, different from the first conductivity type, wherein said second region has a uniform doping.

According to an embodiment, said substrate comprises at least one doped portion of the first conductivity type having a higher doping level than the other doped substrate portions of the first conductivity type, said portion surrounding said first region.

According to an embodiment, said portion surrounds the assembly of said first and second regions.

Another embodiment provides a bipolar transistor manufacturing method using the previously-described PN junction manufacturing method.

According to an embodiment, the emitter region of said bipolar transistor is formed by using the previously-described PN junction manufacturing method.

According to an embodiment, the collector region of said bipolar transistor is formed by using the previously-described PN junction manufacturing method.

Another embodiment provides a bipolar transistor comprising a doped semiconductor substrate of a first conductivity type and at least one third region made of a semiconductor material of a second conductivity type, different from the first conductivity type, wherein said third region has a uniform doping.

According to an embodiment, the third region is the emitter or the collector of the transistor.

According to an embodiment, the transistor further comprises at least one fourth region made of a semiconductor material of a second conductivity type, different from the first conductivity type, wherein said fourth region has a uniform doping.

According to an embodiment, the fourth region is the emitter or the collector of the transistor.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIGS. 1A-1B show a top view and a cross-section view, respectively, of an embodiment of a PN junction;

FIGS. 2A-2C show views illustrating steps of an implementation mode of a method of manufacturing the PN junction of FIGS. 1A-1B;

FIGS. 3A-3B show views illustrating other steps of an implementation mode of a method of manufacturing the PN junction of FIGS. 1A-1B; and

FIGS. 4A-4B show a top view and a cross-section view, respectively, of an embodiment of a bipolar transistor.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made, unless specified otherwise, to the orientation of the figures.

Unless specified otherwise, the expressions “around”, “approximately”, “substantially” and “in the order of” signify within 10%, and preferably within 5%.

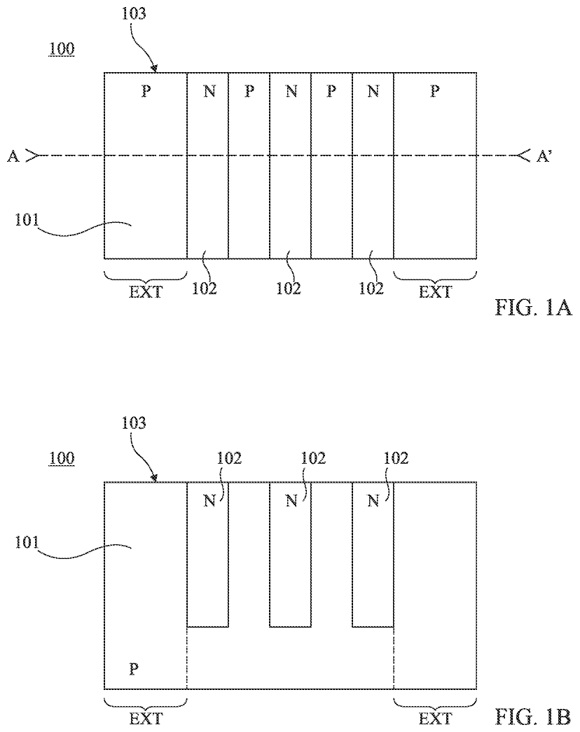

FIGS. 1A-1B comprise a top view and a cross-section view, respectively, of an embodiment of a PN junction 100. More particularly, FIG. 1B is a cross-section view of FIG. 1A along an axis AA′.

PN junction 100 is formed of a doped semiconductor substrate of a first conductivity type, for example, P-type doped, where are formed at least one, preferably a plurality of, trenches 102 filled with a doped semiconductor material of a second conductivity type different from the first conductivity type, for example, N-type doped.

According to an example, trenches 102 extend from an upper surface 103 of substrate 101. According to an example, trenches 102 have a depth in the range from 700 to 800 nm, and a width in the order of 90 nm.

According to an example, when the first conductivity type is type P, substrate 101 is made of a material selected from the group consisting of: silicon, and semiconductor materials comprising silicon. The material of substrate 101 is doped with dopant elements comprising elements from column 13 of Mendeleev's periodic classification of elements, that is, one or a plurality of elements among the following: boron (B), aluminum (Al), gallium (Ga), indium (In), etc. The material filling trenches 102 is doped with dopant elements comprising elements from column 15 of Mendeleev's periodic classification of elements, that is, one or a plurality of elements among the following: nitrogen (N), phosphorus (P), arsenic (As), antimony (Sb), etc. According to another example, the first conductivity type is type N, and the second conductivity type is type P.

According to a practical example, substrate 101 may be made of silicon doped with boron atoms at a dopant concentration in the order of 1.65×10¹² atoms/cm³. Trenches 102 may be filled with silicon doped with arsenic atoms at a dopant concentration in the order of 5×10¹³ atoms/cm³. According to a variant, trenches 102 may be filled with polysilicon doped with phosphorus atoms with a dopant concentration in the order of 2×10²⁰ atoms/cm³. According to another variant, trenches 102 may be filled with a heavily P-type doped material (P+) for example having a dopant concentration in the order of 4×10² atoms/cm³, and the substrate may be made of a heavily N-type doped material (N+), for example having a dopant concentration in the order of 5×10²⁰ atoms/cm³.

PN junction 100 may be used as a conventional diode, it is sufficient for this purpose to install contacting areas accessible on layer 101 and on trenches 102. Thus, according to a first embodiment, PN junction 100 may enable to form a diode comprising a P-type doped substrate having trenches filled with an N-type doped semiconductor material formed therein. According to a second embodiment, PN junction 100 may enable to form a diode comprising an N-type doped substrate having trenches filled with a P-type doped semiconductor material formed therein. In these two embodiments, the substrates may be heavily doped, for example, with doping levels in the range from 10¹⁷ to 10¹⁸ atoms/cm³.

Further, according to an alternative embodiment, certain portions of substrate 101, such as the substrate portions EXT surrounding all the trenches 102, may be more heavily doped than the rest of substrate 101, such as, for example, the portions of substrate 101 located between trenches 102. According to another variant, all or part of the portions of substrate 101 located between trenches 102 may have a doping level higher than the doping level of the material filling trenches 102.

Those skilled in the art will be capable of envisaging other doping types according to the use made of PN junction 100.

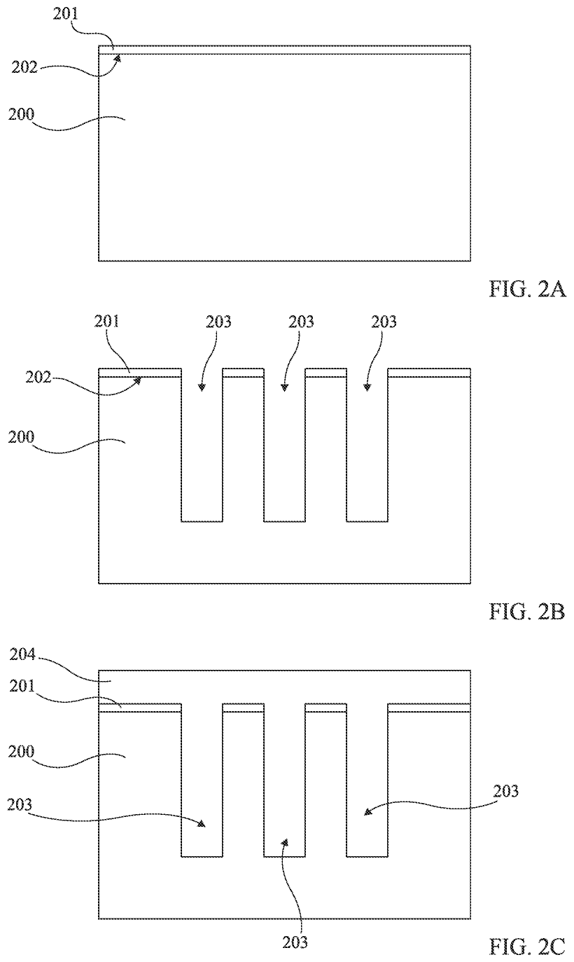

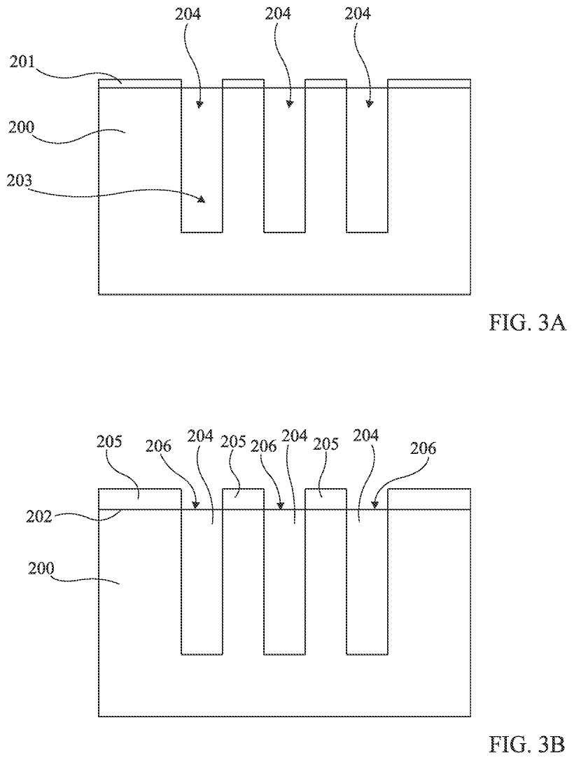

FIGS. 2A-2C and 3A-3B comprise cross-section views illustrating steps of an implementation mode of a method of manufacturing a PN junction of the type of the PN junction 100 described in relation with FIGS. 1A-1B.

In FIG. 2A, a substrate 200 of the type of the substrate 101 described in relation with FIGS. 1A-1B is prepared. Substrate 200 is a doped semiconductor substrate of a first conductivity type.

A layer 201 intended to form a hard mask is deposited on an upper surface 202 of substrate 200. Layer 201 thus enables to protect certain portions of substrate 200, during one or a plurality of manufacturing steps that may follow, such as etch steps and/or steps of deposition of material. Layer 201 may enable to protect one or a plurality of other electronic devices formed inside and/or on top of substrate 200, and may thus enable to co-integrate the PN junction with one or a plurality of other electronic devices. According to an example, layer 201 is a silicon nitride layer (SiN) having a thickness in the range from 60 to 100 nm, for example, in the order of 80 nm.

In FIG. 2B, a first etch step is implemented to give to layer 201 its hard mask function, by etching openings in layer 201. According to an example, layer 201 is etched by a photolithography method.

Further, in FIG. 2B, a second step of etching of substrate 200 is implemented to form trenches 203 extending from the upper surface 202 of substrate 200 and at the level of the openings formed in layer 201. According to an example, trenches 203 have a depth in the range from 700 to 800 nm, and a width in the order of 90 nm.

In FIG. 2C, a doped semiconductor material 204 of a second conductivity type, different from the first conductivity type, is formed on layer 202 and fills trenches 203. According to an embodiment, material 204 has a uniform doping across its entire bulk. According to an example, material 204 is made of doped polysilicon.

According to a first example, material 204 is deposited by implementing a furnace deposition method (Furnace Deposition). According to a second example, material 204 is deposited by implementing an epitaxial growth method. The first example is faster to execute than the second example, but enables to have a sharper PN junction area between the material of substrate 200 and material 204.

In FIG. 3A, the level of the surface of the structure obtained at the step of FIG. 2C is planarized. In other words, the portion of material 204 covering layer 201 and the portion of material 204 extending above surface 202 of substrate 200 are removed. For this purpose, an etch method is implemented, for example, by a chemical mechanical polishing (CMP) method, or a dry etching method. Thereby, only trenches 203 are filled with the material of layer 204.

In FIG. 3B, the hard mask, that is, the etched layer 201, is removed, for example by implementing a wet etching method.

Further, in FIG. 3B, optionally, pads 205 are formed on the upper surface 202 of substrate 200 to protect the PN junction here formed of the short-circuits. Pads 205 are, for example, made of polysilicon or of silicon oxide. According to an example, pads 205 have a height in the range from 80 to 120 nm, for example, in the order of 100 nm. According to an example, pads 205 aims at protecting certain portions of substrate 200 such as the previously-described layer 201.

A plurality of methods may be implemented herein to form pads 205. A first method here comprises a deposition on surface 202 of substrate 200 of a polysilicon layer, this deposition is followed by a step of etching, for example, by photolithography, enabling to remove portions of the poly silicon layer at the level of trenches 204. These steps may be followed by a siliciding step, during which a metal layer, for example, a layer made of an alloy of nickel and palladium, is deposited over the entire obtained structure. The material of the metal layer reacts with the polysilicon to form an electrically-conductive silicide, for example, made of NiSi₂ if the metal layer is made of a nickel and palladium alloy. The areas where there is no polysilicon remain insulating.

A second method comprises a step of deposition of a silicon oxide layer followed by a photolithography step, enabling to keep portions of the silicon oxide layer, forming pads 205, between the trenches to protect them against short-circuits that may be due to a future siliciding step. In the same way as in the first method, a siliciding step may follow this method. This siliciding step is, for example, identical to that described for the first method.

An advantage of this implementation mode is that it enables to form a sharp and abrupt PN junction. More particularly, PN junctions are conventionally obtained by implantation of dopant elements, which forms a doping gradient and not a sharp junction.

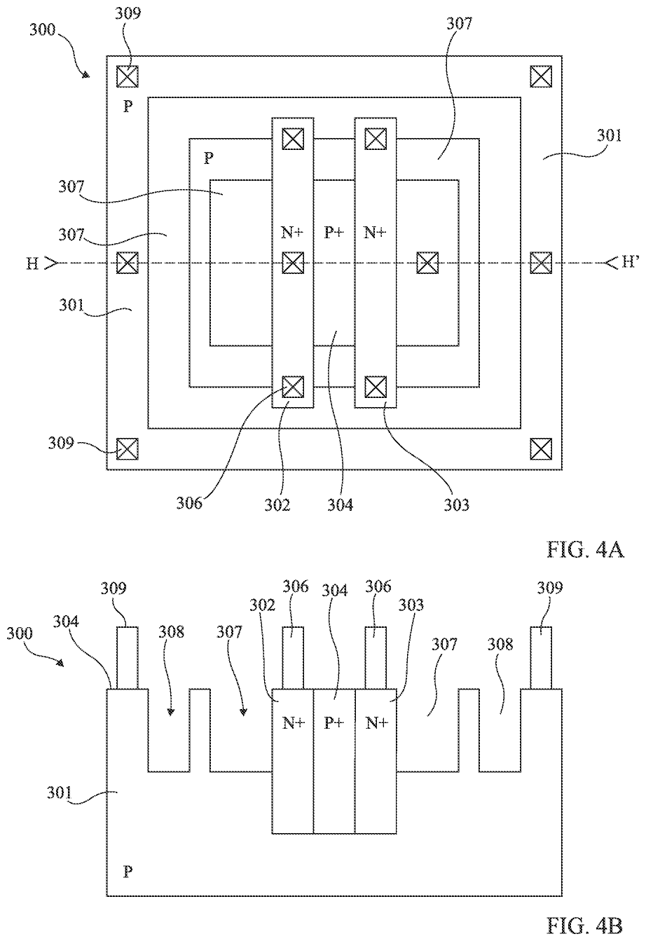

FIGS. 4A-4B comprise a top view and a cross-section view, respectively, of an embodiment of a bipolar transistor 300. More particularly, FIG. 4B is a cross-section view of FIG. 4A along an axis HH′.

Bipolar transistor 300 is formed inside and on top of a wafer of substrate 301 doped with a first conductivity type, for example, type P. According to an example, substrate wafer 301 is made of P-type doped silicon.

Transistor 300 comprises doped regions 302 and 303 of a second conductivity type different from the first type, for example, type N, forming its emitter and collector regions. According to an embodiment, regions 302 and/or 303 are obtained by the method described in relation with FIGS. 2A-2C and FIG. 3A-3B, and have a uniform doping. Regions 302 and 303 thus have been formed from an upper surface 304 of substrate 301. Contacting areas 306 are formed on regions 302 and 303. These contacting areas 306 form emitter and collector contacts of transistor 300.

Transistor 300 further comprises a doped region 304 of the first conductivity type arranged between regions 302 and 303. Region 304 is the base region of transistor 300. Region 304 is, for example, formed by a method of the type of the method described in relation with FIGS. 2A-2C and FIG. 3A-3B. According to an example, in the top view of FIG. 4A, region 304 is shorter than regions 302 and 303.

Transistor 300 further comprises a cavity 307 formed in layer 301 and extending from the upper surface of layer 301 and from a portion of a lateral surface of regions 302 and 303. According to an example, the cavity has a depth smaller than the depth of regions 302, 303, and 304. Cavity 307 has, in top view, a rectangular ring shape surrounding region 304.

Transistor 300 further comprises a cavity 308 formed in layer 301 and extending from the upper surface of layer 301 and around cavity 307. According to an example, the cavity 308 has a depth smaller than the depth of regions 302, 303, and 304, and a depth in the order of the depth of cavity 307. Cavity 308 has, in top view, a rectangular ring shape surrounding cavity 307 and regions 302, 303, and 304.

Cavities 307 and 308 are optional and may enable to form insulating trenches. According to a variant, a single cavity provided by either cavity 307 or cavity 308 is formed.

Contacting areas 309 are formed on the upper surface of layer 301, and preferably outside of cavities 307 and 308. These contacting areas 309 form substrate (base) contacts of transistor 300.

Various embodiments and variants have been described. Those skilled in the art will understand that certain features of these various embodiments and variants may be combined, and other variants will occur to those skilled in the art.

Finally, the practical implementation of the described embodiments and variations is within the abilities of those skilled in the art based on the functional indications given hereabove.

1. A method of manufacturing a PN junction, comprising the following successive steps:
forming at least one trench in a semiconductor substrate of a first conductivity type; and
filling said at least one trench with a semiconductor material of a second conductivity type, different from the first conductivity type.

2. The method according to claim 1, wherein at least two trenches are formed in said substrate.

3. The method according to claim 1, wherein forming at least one trench comprises:
forming a layer made of silicon nitride;
patterning the layer of silicon nitride to include an opening defining a hard mask; and
etching the at least one trench through said opening.

4. The method according to claim 3, wherein the layer made of silicon nitride is in contact with an upper surface of the semiconductor substrate.

5. The method according to claim 1, wherein filling said at least one trench with a semiconductor material comprises performing a furnace deposition of said semiconductor material.

6. The method according to claim 1, wherein filling said at least one trench with a semiconductor material comprises performing an epitaxial deposition of said semiconductor material.

7. The method according to claim 1, wherein the PN junction forms a diode.

8. The method according to claim 1, wherein the PN junction forms part of a bipolar transistor.

9. The method according to claim 8, wherein an emitter region of said bipolar transistor is formed by the PN junction.

10. The method according to claim 8, wherein a collector region of said bipolar transistor is formed by the PN junction.

11. An integrated circuit, comprising:
a doped semiconductor substrate of a first conductivity type;
trenches in the doped semiconductor substrate; and
a first region in one trench of said trenches made of a first semiconductor material of a second conductivity type, different from the first conductivity type, wherein said first region has a uniform doping, to form a first PN junction.

12. The integrated circuit according to claim 11, further comprising a second region in another trench of said trenches made of a second semiconductor material of the second conductivity type, different from the first conductivity type, wherein said second region has a uniform doping.

13. The integrated circuit according to claim 12, wherein said doped semiconductor substrate comprises at least one doped portion of the first conductivity type having a higher doping level than the other doped substrate portions of the first conductivity type, said portion surrounding said first region, and
wherein said portion surrounds an assembly of said first and second regions.

14. The integrated circuit according to claim 12, wherein the first and second regions form the first PN junction and a second PN junction for a bipolar transistor.

15. The integrated circuit according to claim 14, wherein the first region is an emitter of the transistor and the second region is a collector of the transistor.

16. The integrated circuit according to claim 12, further comprising at least one trench in the doped semiconductor substrate surrounding first and second regions.

17. The integrated circuit according to claim 11, wherein said doped semiconductor substrate comprises at least one doped portion of the first conductivity type having a higher doping level than the other doped substrate portions of the first conductivity type, said portion surrounding said first region.

18. An integrated circuit, comprising:
a doped semiconductor substrate of a first conductivity type;
wherein said doped semiconductor substrate includes a first substrate region and a second substrate region, said first substrate region having a higher doping level than the second substrate region;
a plurality of trenches extending into the second substrate region of the doped semiconductor substrate;
a first semiconductor material of a second conductivity type filling said plurality of trenches to form a PN junction for a diode; and
pad material covering an upper surface of the first and second substrate regions of the doped semiconductor substrate.

19. The integrated circuit of claim 18, wherein said pad material comprises polysilicon.

20. The integrated circuit of claim 18, wherein said pad material comprises silicon oxide.

21. An integrated circuit, comprising:
a doped semiconductor substrate of a first conductivity type;
a plurality of first trenches extending into the second substrate region of the doped semiconductor substrate;
a first semiconductor material of a second conductivity type filling said plurality of trenches to form two PN junctions for an emitter and a collector of a bipolar transistor having the doped semiconductor substrate forming a base of the bipolar transistor;
a second trench extending into the second substrate region of the doped semiconductor substrate to surround the bipolar transistor;
a region of the doped semiconductor substrate beyond the second supporting a base contact for the bipolar transistor; and
emitter and collector contacts supported by the first semiconductor material in the plurality of first trenches.

22. The integrated circuit of claim 21, further comprising a third trench extending into the second substrate region of the doped semiconductor substrate to surround both the second trench and the bipolar transistor, wherein said third trench is separate from said second trench.

23. The integrated circuit of claim 22, wherein the second and third trenches are shallower than the plurality of first trenches.

24. The integrated circuit of claim 21, wherein the second trench is shallower than the plurality of first trenches.
